(19) United States
(12) Patent Application Publication
(10) Pub. No.: US 2011/0305254 A1
(43) Pub. Date: Dec. 15, 2011

(54) OPTICAL TRANSMISSION DEVICE

(75) Inventor: Nobuaki Ueki, Kanagawa (JP)

(73) Assignee: FUJI XEROX CO., LTD., Tokyo (JP)

(21) Appl. No.: 12/901,660

(22) Filed: Oct. 11, 2010

(30) Foreign Application Priority Data
Jun. 9, 2010 (JP) 2010-131804

(51) Int. Cl. H01S 5/183

(52) U.S. Cl. 372/45.01

(57) ABSTRACT

An optical transmission device includes: a substrate on which an element portion that includes a semiconductor layer transmitting or receiving an optical signal, and a support portion that includes a conductive semiconductor layer are formed; an optical transmission member that is arranged to face the element portion and the support portion and to be optically coupled to the element portion; and a conductive member that is provided on the support portion and electrically contacts the optical transmission member.

### CROSS-REFERENCE TO RELATED APPLICATION

This application is based on and claims priority under 35 USC 119 from Japanese Patent Application Publication No. 2010-131804 filed on Jun. 9, 2010.

### BACKGROUND

(i) Technical Field

The present invention relates to an optical transmission device.

(ii) Related Art

A communication using optical signals is performed between electronic devices such as a communication device and an information terminal or inside of an electronic device. An optical transmission module, which includes a transmitting side circuit board on which a light emitting element that transmits an optical signal is mounted, a receiving side circuit board on which a light receiving element that receives an optical signal is mounted, and a flexible film optical transmission path that transmits a light from the light emitting element to the light receiving element, has been commercialized for a relatively-short-distance optical communication inside of an electronic device. A film optical waveguide (e.g. slab waveguide) allows greater degree of freedom of packaging an optical transmission module, and makes the size of the optical transmission module small. A Vertical-Cavity Surface-Emitting Laser diode (VCSEL) of which the power consumption is low is used for a light emitting element, for example.

### SUMMARY

According to an aspect of the present invention, there is provided an optical transmission device including: a substrate on which an element portion that includes a semiconductor layer transmitting or receiving an optical signal, and a support portion that includes a conductive semiconductor layer are formed; an optical transmission member that is arranged to face the element portion and the support portion and to be optically coupled to the element portion; and a conductive member that is provided on the support portion and electrically contacts the optical transmission member.

### BRIEF DESCRIPTION OF THE DRAWINGS

Exemplary embodiments of the present invention will be described in detail based on the following figures, wherein:

FIG. 1A is a schematic top view of an optical transmission module in accordance with a first exemplary embodiment of the present invention, and FIG. 1B is a cross-section view of the optical transmission module taken from line A-A;

FIG. 2A is an enlarged view of an element portion of a vertical cavity surface emitting laser, and FIG. 2B is a cross-section view of the element portion taken from line B-B;

FIG. 3A is a cross-section view of a support portion of the vertical cavity surface emitting laser, and FIG. 3B is a top view of the support portion;

FIG. 4A is a top view of an optical transmission module in accordance with a second exemplary embodiment of the present invention, and FIG. 4B is a cross-section view of the optical transmission module taken from line C-C;

FIG. 5 is a schematic cross-section view of an optical transmission module in accordance with a third exemplary embodiment of the present invention; and

FIG. 6 is a plane view illustrating a structure of an optical transmission module in accordance with a fourth exemplary embodiment of the present invention.

### DETAILED DESCRIPTION

A description will now be given, with reference to the accompanying drawings, of exemplary embodiments of the present invention. In the following description, a vertical cavity surface emitting laser will be exemplified as a semiconductor element that transmits optical signals, and a vertical cavity surface emitting laser is abbreviated as a VCSEL. The scale in drawings is exaggerated to understand the feature of the present invention, and is not same as the scale of actual devices.

### First Exemplary Embodiment

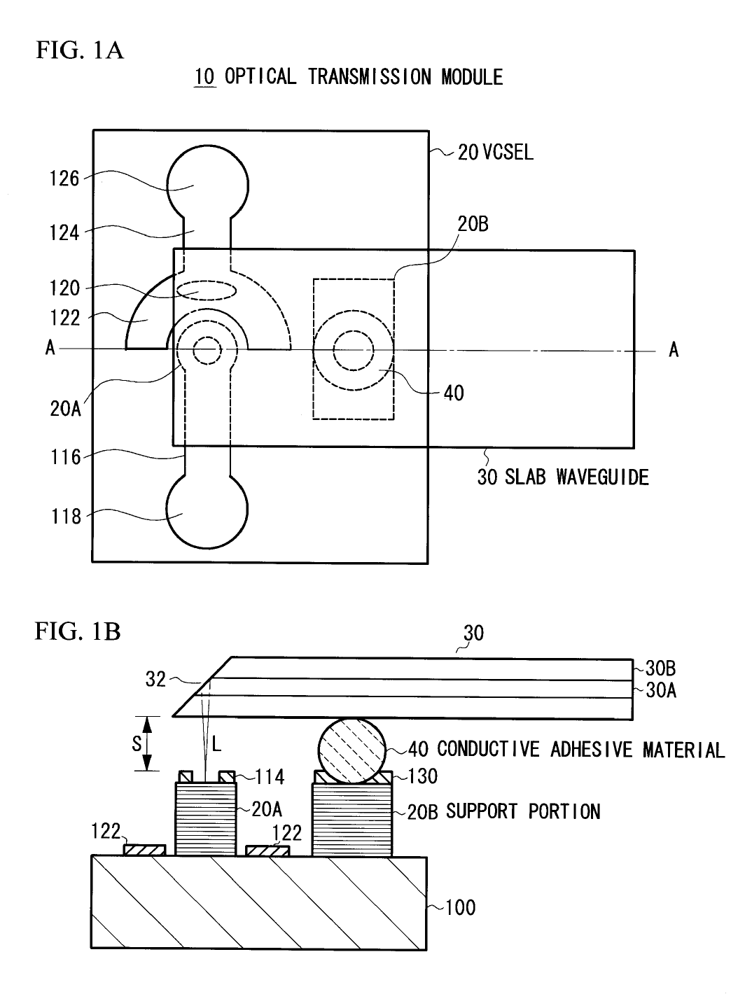

FIG. 1A is a top view of an optical transmission module in accordance with a first exemplary embodiment of the present invention, and FIG. 1B is a cross-section view of the optical transmission module taken from line A-A. An optical transmission module 10 of the first exemplary embodiment includes a VCSEL 20, a slab waveguide 30 as an optical transmission member that is optically-coupled to the VCSEL 20 and transmits a laser beam L from the VCSEL 20, and a conductive adhesive material 40 which provides an electrical connection between the VCSEL 20 and the slab waveguide 30 and a mechanical support.

The VCSEL 20 includes an element portion 20A that has a cylindrical post or mesa on its substrate 100, and a support portion 20B that has a rectangular post or mesa which is formed at a location away from the element portion 20A. The element portion 20A and the support portion 20B are monolithically-formed together on the substrate 100, and both include identical semiconductor layers respectively. A circular p-side electrode pad 118 and a circular n-side electrode pad 126 are formed on the substrate 100. The p-side electrode pad 118 is electrically coupled to a p-type semiconductor layer of the element portion 20A, and the n-side electrode pad 126 is electrically coupled to an n-type semiconductor layer. The element portion 20A includes a vertical resonator structure formed by stacking an n-type semiconductor layer and a p-type semiconductor layer on the substrate, responds to a drive signal which is applied to the p-side electrode pad 118 and the n-side electrode pad 126, and emits a laser beam L to a direction substantially perpendicular to a principal surface of the substrate 100.

The height of the support portion 20B is same as that of the element portion 20A, and the conductive adhesive material 40 is mounted to the top of the support portion 20B via a metallic electrode 130. The conductive adhesive material 40 is electrically coupled to the support portion 20B, and adhesively contacts a back side of the slab waveguide 30. The conductive adhesive material 40 electrically couples the slab waveguide 30 to the support portion 20B and maintains a distance S between an entrance portion 32 of the slab wave guide 30 and the element portion 20A constant by supporting the slab waveguide 30 mechanically.

The slab waveguide 30 is composed of film polymer resin which has flexibility. The slab waveguide 30 includes a core portion 30A of which a refraction index is high, and a clad portion 30B of which a refraction index is lower than that of the core portion 30A, and transmits light by using a total reflection between the core portion 30A and the clad portion 30B. The laser beam emitted from the element portion 20A enters the entrance portion 32 of the slab waveguide 30, and is transmitted to another end that is the emitting side.

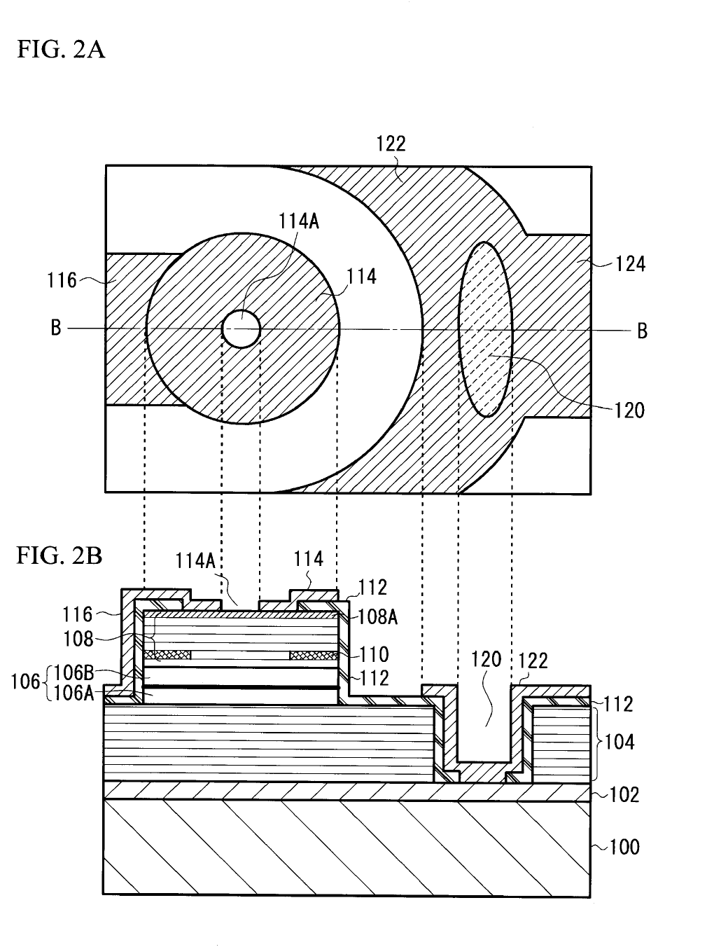

FIG. 2A is an enlarged view of the element portion 20A illustrated in FIG. 1A, and FIG. 2B is a cross-section view of the element portion 20A taken from line B-B. In FIG. 2A, a p-side electrode and an n-side electrode are illustrated with hatching. The typical VCSEL 20 is formed by stacking a buffer layer 102, an n-type Distributed Bragg Reflector (hereinafter, abbreviated as DBR) 104, an active region 106 and a p-type upper DBR 108 on the n-type GaAs substrate 100. The buffer layer 102 is composed of n-type GaAs. The n-type DBR 104 is formed by stacking AlGaAs layers with different Al composition alternately. The active region 106 includes a quantum well layer sandwiched between an lower spacer layer 106A and a upper spacer layer 106B. The p-type upper DBR 108 is formed on the active region 106 by stacking AlGaAs layers with different Al composition alternately. Preferably, a contact layer 108A composed of p-type GaAs is formed at a top layer of the upper DBR 108, and a current confining layer 110 composed of p-type AlAs is formed at a bottom layer of the upper DBR 108 or inside of the upper DBR 108.

The cylindrical element portion 20A is formed on the substrate 100 by etching a semiconductor layer that extends from the upper DBR 108 to the lower DBR 104. When the element portion 20A is formed, the rectangular support portion 20B is formed simultaneously. The current confining layer 110 is exposed on the side surface of the element portion 20A, and has an oxidized region which is selectively oxidized from the side surface, and a circular conductive region (oxidized aperture) surrounded by the oxidized region. As the oxidation rate of AlAs is faster than that of AlGaAs, a region which is selectively oxidized from the side surface to the inside of the element portion 20A can be formed. The diameter of the conductive region to obtain a basic lateral mode is equal to or less than about 5 μm for example. A multi-mode oscillation including a high-order lateral mode occurs when the diameter of the conductive region is bigger than about 5 μm. The center of the conductive region becomes an optical axis of the VCSEL 20.

An interlayer insulating film 112 is formed on whole surface of the substrate including the element portion 20A, and a contact hole is formed to the interlayer insulating film 112 at the top of the element portion 20A. A p-side electrode 114 such as Au or Au/Ti is formed on the interlayer insulating film 112, and the p-side electrode 114 is ohmic connected to the contact layer 108A through the contact hole. A circular opening 114A is formed at the center of the p-side electrode 114, and the center of the opening 114A is substantially on the optical axis. This opening 114A becomes a beam window from which a laser beam is emitted to the direction perpendicular to the principal surface of the substrate 100.

The p-side electrode 114 is coupled to a metallic wiring 116 as illustrated in FIG. 1A. The metallic wiring 116 is guided along a side wall of the element portion 20A, and is coupled to a circular electrode pad 118 formed on the surface of the substrate 100. The electrode pad 118 is electrically connected to a wiring pattern on a circuit board on which the substrate 100 is mounted with a bonding wire or the like.

An elliptical or rectangular via hole 120 which reaches to the buffer layer 102 is formed at the location close to the element portion 20A by etching a semiconductor layer. A contact hole for exposing the buffer layer 102 is formed in the interlayer insulating film 112 covering the via hole 120. An n-side electrode 122 is formed on the interlayer insulating film 112 in a region including the via hole 120, and the n-side electrode 122 is electrically coupled to the buffer layer 102 through the contact hole. The n-side electrode 122 has an arcuate pattern surrounding the half of the element portion 20A as illustrated in FIG. 1A. The n-side electrode 122 is coupled to a metallic wiring 124 which extends on the substrate 100, and the metallic wiring 124 is coupled to a circular electrode pad 126. The electrode pad 126 is electrically connected to the wiring on a circuit board on which the substrate 100 is mounted with a bonding wire or the like.

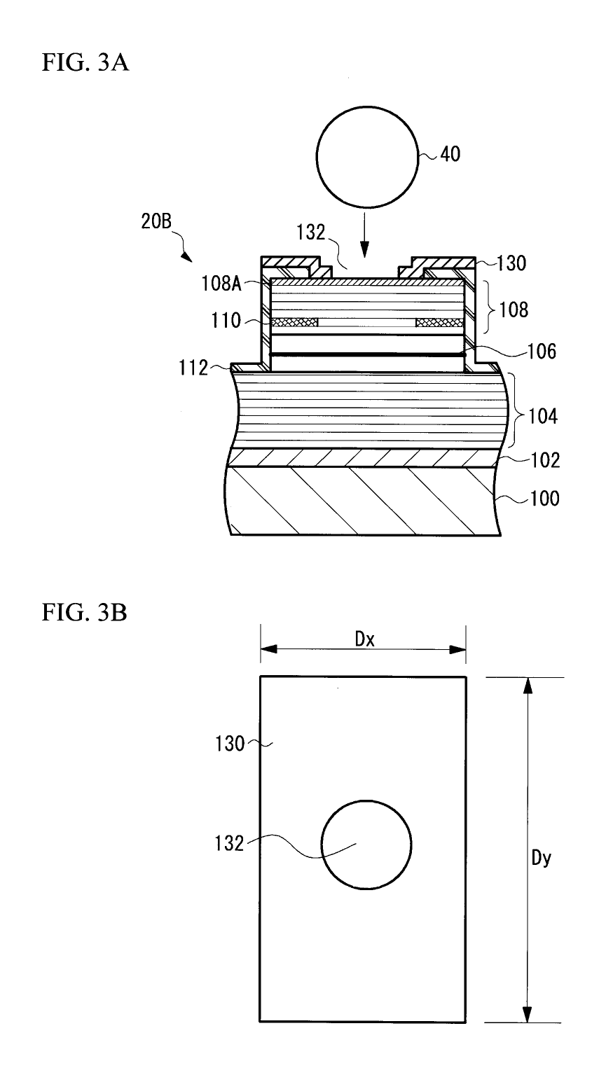

FIG. 3A is a cross-section view of the support portion 20B formed in the VCSEL, and FIG. 3B is a top view of the support portion 20B. The support portion 20B has a rectangular post or mesa structure which is formed by etching a semiconductor layer that extends from the upper DBR to the lower DBR. The support portion 20B includes a semiconductor layer identical with that of the element portion 20A, and the metallic electrode 130 is formed on the contact layer 108A which is a top layer. A circular recessed portion 132 for positioning and holding the conductive adhesive material 40 is formed at the center part of the metallic electrode 130. The size of the recessed portion 132 is decided based on shape, material and viscosity of the conductive adhesive material 40 to be mounted. Preferably, the metallic electrode 130 is composed of same material as that of the p-side electrode 114, and formed at the same time as the pattern of the p-side electrode 114 is formed. As described above, a current pathway from the metallic electrode 130 to the n-side electrode 122 is formed.

The support portion 20B has a width Dx in a shorter direction and a width Dy in a longer direction as illustrated in FIG. 3B. Preferably, the width Dy is larger than the diameter of the top of the element portion 20A, and is set so that the rate (Dy/D) to the width D that is a width in a shorter direction of the slab waveguide 30 becomes constant. The support of the slab waveguide 30 becomes stable by making a contacting area by the conductive adhesive material 40 large.

The conductive adhesive material 40 is provided to the inside of the recessed portion 132 of the metallic electrode 130. Conductive resin, silver paste, DOTITE, (trade name) available from FUJIKURAKASEI CO., LTD. and the like can be used for the conductive adhesive material 40. The conductive adhesive material 40 can be curable resin which is potted to the inside of the recessed portion 132 of the metallic electrode 130 in a gel condition, and conductively cures after a certain period of time, or can be a conductive material which is an ultraviolet curable type, visible light curing type or thermal curing type and has a adherence property.

The conductive adhesive material 40 is provided on the support portion 20B as described above, supports the slab waveguide 30 mechanically, and provides a discharge pathway to the slab waveguide 30. Moreover, the conductive adhesive material 40 compensates a height by which the top end (entrance portion) 32 of the slab waveguide 30 is away from the element portion 20A at a certain distance S.

As the static electricity is easily charged to the slab waveguide 30 made of polymer resin during a packaging process or operation in the optical transmission module 10 which has a clearance between the VCSEL 20 and the slab waveguide 30, there has been a case that a light element is damaged by electrostatic discharge caused by discharge which occurs at the moment that the slab waveguide 30 bows and contacts a conductive material. This is also because the accidental contact easily occurs because an optical waveguide composed of polymer resin has a flexible property in addition to the necessity that the VCSEL 20 is closely-aligned to the slab waveguide 30 till the clearance between them becomes about 100 μm to improve a coupling efficiency of the VCSEL 20 and the slab waveguide 30. A countermeasure against static electricity of the optical transmission module is necessary because there is a time that a static electricity is easily generated depending on a usage environment and a season.

In the optical transmission module 10 of the first exemplary embodiment, the static electricity which is generated on the surface of the slab waveguide 30 is guided to the support portion 20B of the VCSEL 20 through the conductive adhesive material 40, and passes a p-type semiconductor layer 108 and an n-type semiconductor layer 104 of the support portion 20B from the metallic electrode 130, and is discharged to the n-side electrode 122. Thus, as the slab waveguide 30 is not charged because a static electricity is practically discharged, the static electricity is not discharged to the element portion 20A, and the element portion 20A can be protected from electrostatic breakdown even though the entrance portion 32 which is a top end of the slab waveguide 30 bows and contacts the VCSEL 20. Moreover, as the support portion 20B has a stacking layer structure same as that of the element portion 20A, and has an area larger than that of the element portion 20A, the resistance value is small compared to the element portion 20A, and it becomes difficult for a surge current to flow into the element portion 20A. In addition, the support portion 20B becomes a marker for aligning the slab waveguide 30 to the element portion 20A, and has a structure that prevents the conductive adhesive material 40 from flowing out by the recessed portion 132 formed in the metallic electrode 130.

### Second Exemplary Embodiment

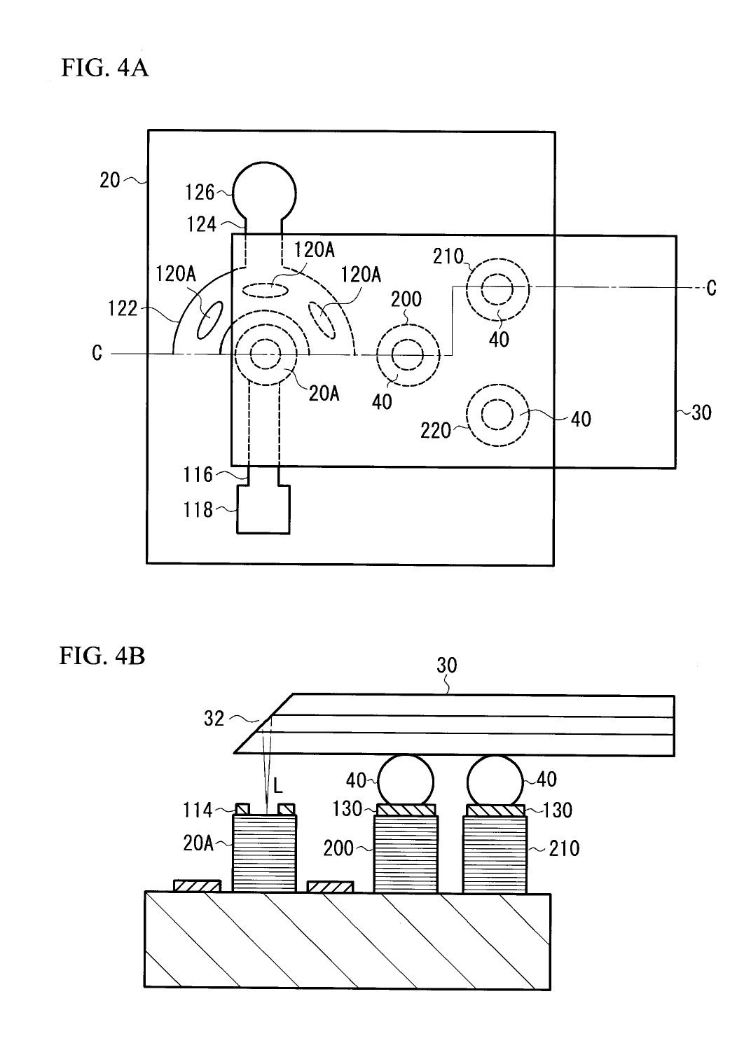

A description will now be given of a second exemplary embodiment. FIG. 4A is a top view of an optical transmission module in accordance with the second exemplary embodiment, and FIG. 4B is a cross-section view of the optical transmission module taken from line C-C. In the second exemplary embodiment, multiple via holes 120A are formed in the element portion 20A of the VCSEL 20, and the n-side electrode 122 is electrically coupled to the buffer layer 102 through these multiple via holes 120A. In addition, three support portions 200, 210 and 220 each having a circular post or mesa structure are formed on the substrate 100 of the VCSEL 20. Each of three support portion 200, 210 and 220 has a semiconductor layer identical with that of the element portion 20A, and conductive adhesive materials 40 are mounted on their top through metallic electrodes 130 respectively in the same manner as the first exemplary embodiment. Three conductive adhesive materials 40 are bonded to the back side of the slab waveguide 30, and support the slab waveguide 30 mechanically. The support of the slab waveguide 30 of which the width is wide can become stable by using three conductive adhesive materials. Moreover, as the contacting area by support portions 200, 210 and 220 becomes large, a resistance can become small and it becomes difficult for the surge current to flow into the element portion 20A.

Preferably, three support portions 200, 210, and 220 are arranged to be symmetrical to the line passing through the support portion 200. In addition, three support portions 200, 210 and 220 are arranged at equal distance, and support the slab waveguide 30 with equal force. It is preferable that diameters of support portions 200, 210 and 220 are larger than that of the element portion 20A. In addition to this, it is possible to form more than four support portions on the substrate, and make a shape and size of each support portion different.

### Third Exemplary Embodiment

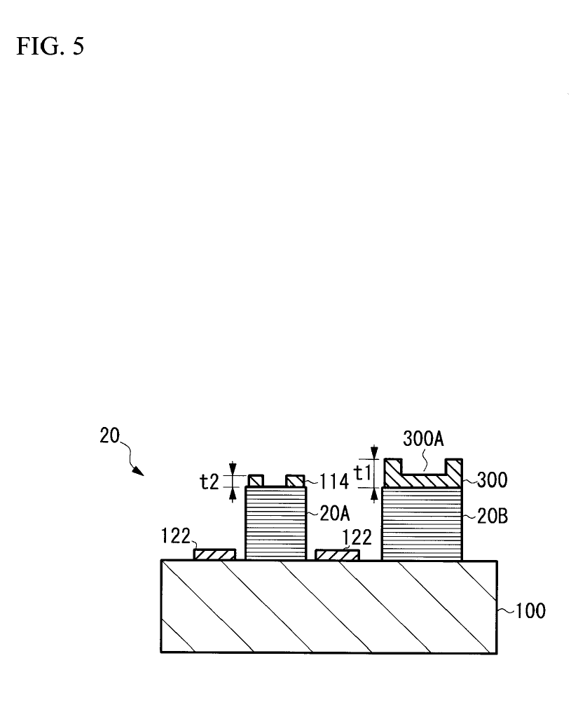

A description will now be given of a third exemplary embodiment. FIG. 5 is a schematic cross section view of a VCSEL of an optical transmission module in accordance with the third exemplary embodiment. In the third exemplary embodiment, the film thickness of a metallic electrode 300 formed on the top of the support portion 20B is larger than that of the p-side electrode 114 of the element portion 20A. As illustrated in FIG. 5, the film thickness t1 of the metallic electrode 300 of the support portion 20B is formed to be larger than the film thickness t2 of the p-side electrode 114 (t1>t2). If the thickness in the height direction of the conductive adhesive material 40 decreases by more than a certain amount when the conductive adhesive material 40 contacts the slab waveguide 30, it becomes impossible to compensate a distance S between the entrance portion 32 which is the top end of the slab waveguide 30 and the element portion 20A. By making the film thickness of the metallic electrode 300 be t1, it becomes possible to compensate the distance S between the entrance portion 32 of the slab waveguide 30 and the element portion 20A even though the shape of the conductive adhesive material 40 changes.

In the third exemplary embodiment, a concave portion 310 for holding and positioning the conductive adhesive material 40 is formed on the surface of the metallic electrode 300. As the support portion 20B does not emit the light, it is not necessary for the concave portion 310 to expose the contact layer 108A. The third exemplary embodiment is applicable to the VCSEL including multiple support portions as described in the second exemplary embodiment.

### Fourth Exemplary Embodiment

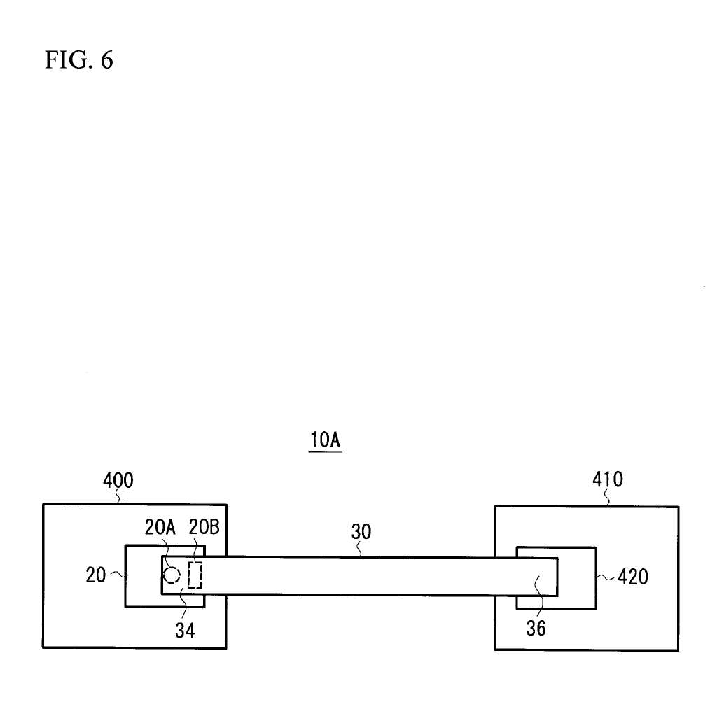

FIG. 6 illustrates an optical transmission module 10A in accordance with a fourth exemplary embodiment. The fourth exemplary embodiment illustrates a structure of the optical transmission module 10A including a semiconductor light receiving element which receives an optical signal transmitted from a semiconductor light emitting element. The VCSEL 20 is mounted on the transmitting-side circuit board 400, and one end 34 of the slab waveguide 30 is supported by the VCSEL 20. The p-side electrode pad 118 and the n-side electrode pad 126 of the VCSEL 20 illustrated in FIG. 1A are electrically coupled to a given wiring pattern on the circuit board 400 with a bonding wire. A light receiving element 420 is mounted on a receiving-side circuit board 410, and the other end 36 of the slab waveguide 30 is supported above the light receiving element 420. The end 36 is optically-coupled to the light receiving element 420. An optical signal transmitted from the slab waveguide 30 is converted to the electric signal by the light receiving element 420, and the converted electric signal is provided to the given wiring pattern on the circuit board 410.

As the flexible slab waveguide 30 is coupled to the support portion 20B of the VCSEL 20 through the conductive adhesive material 40, the static electricity generated on the surface of the slab waveguide 30 is discharged by the support portion 20B. Accordingly, it is possible to protect the light receiving element 420 from electrostatic breakdown even though the end 36 of the slab waveguide 30 contacts the light receiving element 420.

The present invention is applicable to the light receiving element side. More specifically, provide the support portion composed of same material as that of the light receiving element on the light receiving element 420 illustrated in FIG. 1A and provide the conductive adhesive material on the support portion so that the conductive adhesive material supports the end 36, which locates on the light receiving element side, of the slab waveguide 30. According to this, the static electricity charged to the slab waveguide can be discharged to the light receiving element 420 on the light receiving element side. The light receiving element can be a cylindrical or rectangular surface type light receiving element formed by stacking an n-type semiconductor layer and a p-type semiconductor layer on the substrate for example, and performs a photoelectric conversion to the light entering from the direction substantially perpendicular to the principal surface of the substrate. The support portion forms a current pathway composed of a semiconductor layer identical with that of the light receiving element, and discharges the static electricity from the slab waveguide. In addition, the light receiving element may have a structure where n-type or p-type semiconductor layers are stacked on a p-type or n-type silicon substrate. In that case, the support portion can stack n-type or p-type semiconductor layers on a silicon substrate and applies the conductive adhesive material thereon.

In the first exemplary embodiment, the description was given by using an example where the n-side electrode of the VCSEL is formed on the surface of the substrate. However, the n-side electrode may be formed on the back side of the substrate. In this case, the n-type GaAs substrate is used for a substrate. In above exemplary embodiments, a description was given by using the slab waveguide as an optical waveguide. However, the present invention is applicable to optical waveguides and optical fibers having a circular cross-section surface. Moreover, in the above exemplary embodiments, a description was given by using the VCSEL that has selective oxidation type current confining layer as a light emitting element. However, the light emitting element may be a simple air post structure type VCSEL, a proton injection type VCSEL or a light emitting diode which does not have a resonator structure. The shape of the element portion and the support portion are not limited, and may be a columnar shape or other shape than the columnar shape.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various exemplary embodiments and with the various modifications as are suited to the particular use contemplated. It is intended that the scope of the invention be defined by the following claims and their equivalents.

What is claimed is:

1. An optical transmission device comprising:
a substrate on which an element portion that includes a semiconductor layer transmitting or receiving an optical signal, and a support portion that includes a conductive semiconductor layer are formed;
an optical transmission member that is arranged to face the element portion and the support portion and to be optically coupled to the element portion; and
a conductive member that is provided on the support portion and electrically contacts the optical transmission member.

2. The optical transmission device according to claim 1, wherein the element portion includes a first semiconductor layer of a first conductive type and a second semiconductor layer of a second conductive type which is a different conductive type from the first conductive type, and has a light emitting or light receiving surface in a normal direction of the substrate; and
the support portion includes a semiconductor layer comprised of a material same as that of the element portion.

3. The optical transmission device according to claim 1, wherein the support portion includes a metallic electrode that is electrically coupled to the conductive semiconductor layer in a surface facing to the optical transmission member; and
a recessed portion for holding the conductive member is formed in the metallic electrode.

4. The optical transmission device according to claim 1, wherein the conductive member is bonded to the optical transmission member with adhesiveness.

5. The optical transmission device according to claim 1, wherein a film thickness of the metallic electrode formed in the surface of the support portion facing to the optical transmission member is larger than a film thickness of an metallic electrode formed on a top of the element portion.

6. The optical transmission device according to claim 1, wherein an area of the surface of the support portion facing to the optical transmission member is larger than an area of the top of the element portion.

7. The optical transmission device according to claim 1, wherein a plurality of support portions are formed on the substrate; and
the optical transmission member is supported through conductive members that are provided to surfaces of the plurality of support portions facing to the optical transmission member respectively.

8. The optical transmission device according to claim 1, wherein the optical transmission member is comprised of resin that has flexibility.

9. An optical transmission device comprising:
a transmitting side substrate on which a first element portion that includes a semiconductor layer transmitting an optical signal, and a first support portion that includes a conductive semiconductor layer are formed;
a receiving side substrate on which a second element portion that receives an optical signal is formed;
an optical transmission member that includes a first end portion that an optical signal enters, an optical transmission path which transmits an optical signal that enters the first end portion, and a second end portion which emits a transmitted optical signal; and
a first conductive member which is provided on the first support portion of the transmitting side substrate;
wherein the optical transmission member is supported by the first support portion through the first conductive member so that the first end portion is optically coupled to the first element portion; and
the second end portion is optically coupled to the second element portion.

10. The optical transmission device according to claim 9, wherein a second support portion including a conductive semiconductor layer is formed on the receiving side substrate;
a second conductive member is provided on the second support portion; and
the optical transmission member is supported by the second support portion through the second conductive member so that the second end portion is optically coupled to the second element portion.
